(19) United States
(12) Patent Application Publication
(10) Pub. No.: US 2010/0001352 A1
(43) Pub. Date: Jan. 7, 2010

(54) Semiconductor device and method of manufacturing the same

(75) Inventors: Gen Tsutsui, Kanagawa (JP); Tadashi Fukase, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 12/458,196

(22) Filed: Jul. 2, 2009

(30) Foreign Application Priority Data
Jul. 7, 2008 (JP) 2008-176779

(51) Int. Cl. H01L 29/78; H01L 21/336

(52) U.S. Cl. 257/408; 438/286; 257/E29.266; 257/E21.437

(57) ABSTRACT

A semiconductor device includes a MOSFET having: a gate electrode provided over a silicon substrate; and a first impurity diffusion region and a second impurity diffusion region provided in the silicon substrate in different sides of said first gate electrode, wherein the MOSFET has an extension region in an upper section of the first impurity diffusion region and no extension region in an upper section of the second impurity diffusion region, and has a first silicide layer over the first impurity diffusion region and has no silicide layer over the second impurity diffusion region in vicinity of a side edge of the gate electrode.

This application is based on Japanese patent application No. 2008-176,779, the content of which is incorporated hereinto by reference.

### BACKGROUND

1. Technical Field

The present invention relates to a semiconductor device and method of manufacturing thereof.

2. Related Art

Transistors having asymmetric configuration for source and drain (that is, asymmetric transistors) are described in U.S. Pat. No. 5,408,115 and Japanese Patent Laid-Open No. 2005-191,506.

U.S. Pat. No. 5,408,115 discloses a transistor having a side wall composed of oxide film/nitride film/oxide film and a control gate having a side spacer-like geometry disposed outside of the side wall. The transistor has a configuration, in which no extension is implanted in a drain end.

Japanese Patent Laid-Open No. 2005-191,506 discloses an N-channel transistor, which constitutes a source offset-type nonvolatile memory cell. The transistor involves a deep N-well, a P-well and a source function as an emitter, a base and a collector, respectively by applying a bipolar mode, and electric charges being implanted in an offset spacer in vicinity of a source region to provide a controlled threshold voltage. In addition, the transistor is configured to include no extension implanted in the source end.

In addition, asymmetric transistors are also described in Japanese Patent Laid-Open No. 2000-208,764, Japanese Patent Laid-Open No. 2000-156,500, Japanese Patent Laid-Open No. H11-220,122 (1999) and Japanese Patent Laid-Open No. H02-30,185 (1990).

Meanwhile, an upper section of the source/drain regions may be silicidated in order to reduce a contact resistance in the upper surface of the source/drain regions of the transistor.

However, the present inventors have examined a silicidation of a source/drain regions of an asymmetric transistor, and have found that there is a concern for causing junction leakage in a region having no extension region, when an extension is provided in only one of the source/drain regions.

### SUMMARY

According to one aspect of the present invention, there is provided a semiconductor device, comprising: a first field effect transistor having: a first gate electrode provided over a silicon substrate; and a first and a second impurity diffusion regions provided in the silicon substrate in different sides of the first gate electrode, wherein the first field effect transistor has an extension region in an upper section of the first impurity diffusion region and no extension region in an upper section of the second impurity diffusion region, and has a first silicide layer over the first impurity diffusion region and has no silicide layer over the second impurity diffusion region in vicinity of a side edge of the first gate electrode.

According to another aspect of the present invention, there is provided a method of manufacturing a semiconductor device, comprising: forming a first gate electrode in an upper section of a silicon substrate; ion-implanting a impurity of first type conductivity selectively in one side of the first gate electrode to form an extension region; implanting the impurity of first type conductivity in a section of the silicon substrate around the first gate electrode to form a first impurity diffusion region in the one side of the first gate electrode and to form a second impurity diffusion region facing the first impurity diffusion region across the first gate electrode; forming an insulating film so as to cover the upper section of the second impurity diffusion region in vicinity of the side edge of the first gate electrode; and forming a metallic film on a element formation surface of the silicon substrate having the insulating film provided thereon, and then causing a reaction of a metal in the metallic film with silicon in the silicon substrate to form a first silicide layer in the upper section of the first impurity diffusion region.

In the present invention, an extension region is provided only in one of the first impurity diffusion region and the second impurity diffusion region, and no silicidation is conducted for a region in vicinity of an end of the other one of the impurity diffusion regions without having an extension region in the side of the first gate electrode. This allows effectively inhibiting the junction leakage in the side having no extension region, when an extension region is provided only in one impurity diffusion region.

In addition to above, any combinations of the respective configurations or a conversion in the representation of the present invention among a process, a device or the like may be included in the scope of the present invention.

According to the present invention, an extension region is provided only in one of the source and the drain and no silicidation is conducted in the end of the other one in the side of the gate without having an extension region, so that a junction leakage of an asymmetric transistor can be inhibited.

### BRIEF DESCRIPTION OF THE DRAWINGS

The above and other objects, advantages and features of the present invention will be more apparent from the following description of certain preferred embodiments taken in conjunction with the accompanying drawings, in which:

FIG. 1 is a cross-sectional view illustrating a configuration of a semiconductor device in an embodiment;

FIGS. 2A and 2B are schematic diagrams describing a method of manufacturing a semiconductor device of FIG. 1;

FIG. 3 is a plan view describing a method of manufacturing a semiconductor device of FIG. 1;

FIGS. 4A and 4B are schematic diagrams illustrating a configuration of a semiconductor device in an embodiment;

FIGS. 5A and 5B are plane views describing a method of manufacturing a semiconductor device of FIGS. 4A and 4B;

FIGS. 6A and 6B are plane views illustrating configurations of semiconductor devices in an embodiment;

FIGS. 7A and 7B are schematic diagrams illustrating a configuration of a semiconductor device in an embodiment;

FIGS. 8A and 8B are plane views describing a method of manufacturing a semiconductor device of FIG. 7;

FIG. 9 is a plan view illustrating a configuration of a semiconductor device in an embodiment;

FIG. 10 is a plan view illustrating a configuration of a semiconductor device in an embodiment; and

FIG. 11 is a cross-sectional view illustrating a configuration of a semiconductor device.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferable embodiments of the present invention will be described in reference to the annexed figures. In all figures, an identical numeral is referred to a component commonly appeared in the drawings, and duplicated descriptions for such component will not be repeated.

### First Embodiment

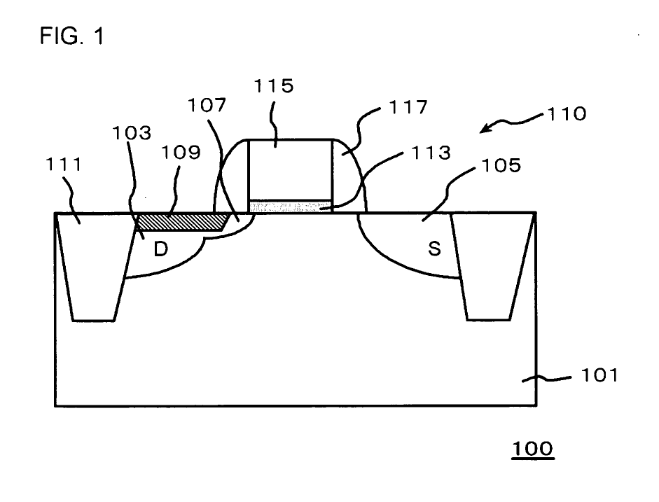

FIG. 1 is a cross-sectional view, illustrating a configuration of a semiconductor device of the present embodiment. A semiconductor device 100 shown in FIG. 1 includes a first field effect transistor (metal-oxide semiconductor field-effect transistor (MOSFET) 110), which includes a first gate electrode (gate electrode 115) provided over a silicon substrate 101, and a first and a second impurity diffusion regions (first impurity diffusion region 103, second impurity diffusion region 105) provided in the silicon substrate 101 in different sides of the gate electrode 115.

The MOSFET 110 is an asymmetric MOSFET, in which an extension region is provided only in one of a source region and a drain region. An extension region 107 is provided in the upper section of the first impurity diffusion region 103, and no extension region is provided in the upper section of the second impurity diffusion region 105. Descriptions will be made as follows in reference to a configuration, in which a drain region serves as the first impurity diffusion region 103, and a source region serves as the second impurity diffusion region 105.

A first silicide layer 109 is included on the first impurity diffusion region 103 in the MOSFET 110. On the other hand, no silicide layer is included on the second impurity diffusion region 105 in vicinity of a side edge of the gate electrode 115. In other words, the section of the silicon substrate 101 in the side edge of the gate electrode 115 is selectively silicidated in a region where the extension region 107 is provided. The MOSFET 110 may be, for example preferably employed as a MOSFET composing a nonvolatile memory.

In the next, a method of manufacturing the semiconductor device 100 will be described. The method of manufacturing the semiconductor device 100 may include, for example, the following steps.

Step 11: forming a first gate electrode (gate electrode 115) in an upper section of the silicon substrate 101;

Step 12: ion-implanting a impurity of first type conductivity selectively in one side of the gate electrode 115 to form the extension region 107;

Step 13 : implanting the impurity of the first type conductivity in a section of the silicon substrate 101 around the gate electrode 115 to form a first impurity diffusion region 103 in the above one side and to form a second impurity diffusion region 105, which faces the first impurity diffusion region 103 across said first gate electrode 115;

Step 14: forming an insulating film (silicon oxide film 123) so as to cover the upper section of the second impurity diffusion region 105 in vicinity of the side edge of the gate electrode 115; and

Step 15: forming a metallic film on an element formation surface of the silicon substrate 101 having the silicon oxide film 123 provided thereon, and then causing a reaction of a metal in the metallic film with silicon in the silicon substrate 101 to form a first silicide layer 109 in the upper section of the first impurity diffusion region 103.

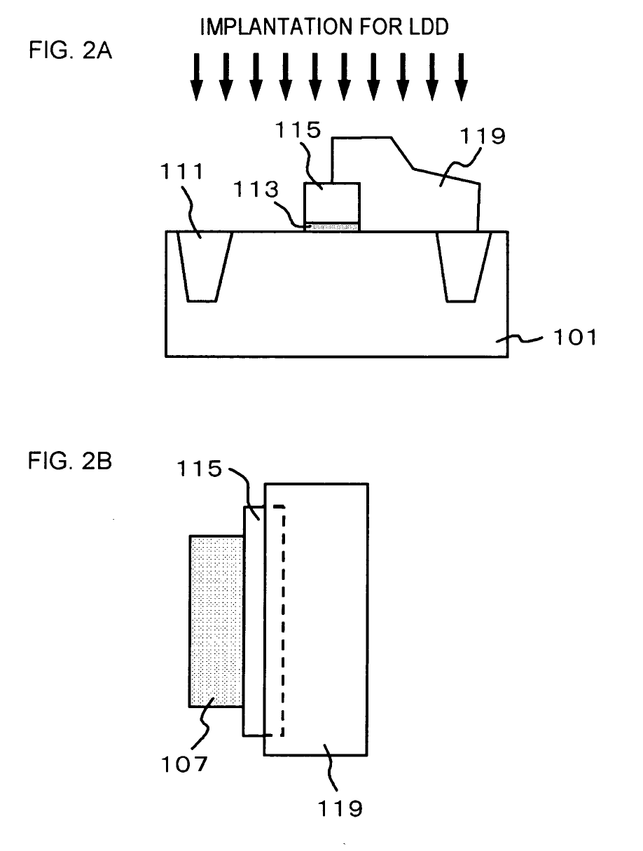

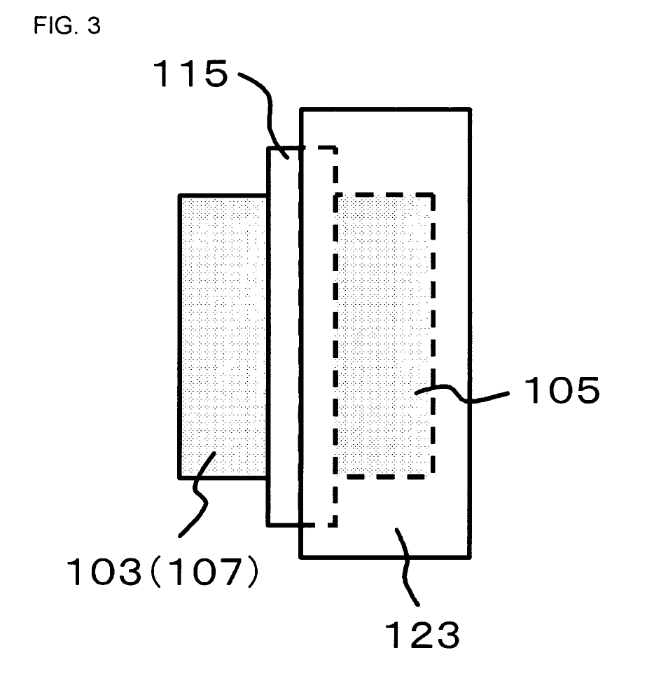

The method of manufacturing the semiconductor device 100 will be fully described in reference to FIG. 2A, FIG. 2B and FIG. 3. FIG. 2A, FIG. 2B and FIG. 3 are diagrams for describing the method of manufacturing the semiconductor device 100. FIG. 2B shows a top view of a partial section in FIG. 2A.

First of all, as shown in FIG. 2A, an element isolation region 111 is formed in the silicon substrate 101 according to, for example, a shallow trench isolation (STI) configuration, by a known method. The element isolation region 111 may alternatively be formed by other known method such as, for example, a local oxidation of silicon (LOCOS) process and the like.

Next, the gate insulating film 113 is formed over the surface of the silicon substrate 101. In such case, for example, a silicon oxide film formed by thermally oxidizing the surface of the silicon substrate 101, may be employed for the gate insulating film 113. The thickness of the gate insulating film 113 may be, for example, approximately 1 nm to 10 nm. Subsequently, a polycrystalline silicon film, which will serve as the gate electrode 115, is formed on the gate insulating film 113 to have a thickness of about 50 nm to 200 nm. Then, the gate insulating film 113 and a polycrystalline silicon film are selectively dry-etched so as to leave predetermined regions to provide a geometry of a gate.

Subsequently, a silicon oxide film, which will serve as a side wall insulating film 117 (FIG. 1) covering the side wall of the gate electrode 115, is formed by a known process, and then the resist film 119 is formed over the entire surface of the silicon substrate 101, and the formed resist film 119 is patterned by selectively removing predetermined areas. In FIG. 2A, the resist film 119 is provided from the upper section of the element isolation region 111 to the upper section of the gate electrode 115 so as to cover the region for forming the second impurity diffusion region 105.

An impurity of first type conductivity (for example, n-type) is ion-implanted in a portion of the silicon substrate 101 in vicinity of the surface of the first impurity diffusion region 103 through the mask of the resist film 119 (shown as “implantation for LDD” in FIG. 2A, LDD is an abbreviation of lightly doped drain). In the first impurity diffusion region 103 (FIG. 1) and the second impurity diffusion region 105 (FIG. 1), the extension region 107 is selectively formed over the first impurity diffusion region 103 by such process (FIG. 2B).

Then the resist film 119 is removed to expose the element formation surface of the silicon substrate 101. Subsequently, a silicon oxide film, which will serve as a side wall insulating film 117 (FIG. 1) covering the side wall of the gate electrode 115, is formed by a known process, and then an impurity of the first type conductivity (for example, n-type) is injected in both sides of the gate electrode 115 in the silicon substrate 101 to form the first impurity diffusion region 103 and the second impurity diffusion region 105, which function as source/drain regions.

Then, the silicon oxide film 123 serving as a silicide block is selectively formed in predetermined regions on the silicon substrate 101 (FIG. 3). Specifically, the silicon oxide film 123 is formed at least in vicinity of the side edge of the gate electrode 115 so as to cover the upper section of the second impurity diffusion region 105. More specifically, the silicon oxide film 123 is formed in vicinity of the side edge of the gate electrode 115 over the entire region for forming the second impurity diffusion region 105. In addition, in the example of FIG. 3, the silicon oxide film 123 is formed so as to cover from the upper section of the gate electrode 115 to the upper section of the second impurity diffusion region 105 and to cover the entire surface of second impurity diffusion region 105 from the upper view point.

Subsequently, the upper section of the first impurity diffusion region 103 having the extension region 107 is silicidated. In this case, as shown in FIG. 3, the previously formed silicon oxide film 123 is utilized as a silicide block to selectively silicidate the upper section of the first impurity diffusion region 103 to provide the first silicide layer 109, in the first impurity diffusion region 103 and the second impurity diffusion region 105. Therefore, the semiconductor device 100 shown in FIG. 1 may be provided. In addition to above, after conducting the above-mentioned procedure, certain elements or interconnect layers may be additionally formed in the semiconductor device 100. Alternatively, in such case, the semiconductor device 100 may also be utilized in the next process step without removing the silicon oxide film 123 employed as the silicide block.

Next, functions and advantages of the semiconductor device according to the present embodiment will be described. In the present embodiment, among the first impurity diffusion region 103 and the second impurity diffusion region 105 functioning as source/drain regions, the extension region 107 is provided only in the side of the first impurity diffusion region 103, and the second impurity diffusion region 105 having no extension region 107 in the side edge of the gate electrode 115 is not silicidated.

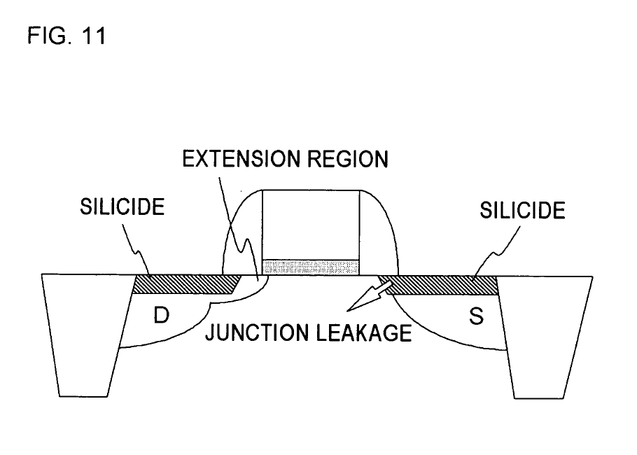

Here, an example for silicidating both of the source/drain regions in the transistor having the extension region in one of the source/drain regions is shown in FIG. 11. As shown in FIG. 11, when the both of the source/drain regions are simultaneously silicidated, there is a concern that the silicide layer formed in the side having no extension region (the side of the source (S) in FIG. 11) may extend beyond the impurity diffusion region in the side of the gate electrode. Thus, there is a concern that an electricity leakage may be caused in the junction between the impurity diffusion region and the well in the side of the source having no extension region, deteriorating the performances of the transistor.

On the contrary, since the second impurity diffusion region 105 having no extension region 107 in the side edge of the gate electrode 115 is not silicidated in the present embodiment, the junction leakage in the second impurity diffusion region 105 having no extension region 107 can be effectively inhibited even if the configuration having the extension region 107 in one side.

While the exemplary implementation having a single MOSFET 110 provided in the silicon substrate 101 have been illustrated in FIG. 1, a plurality of MOSFETs 110 may alternatively be provided in the silicon substrate 101.

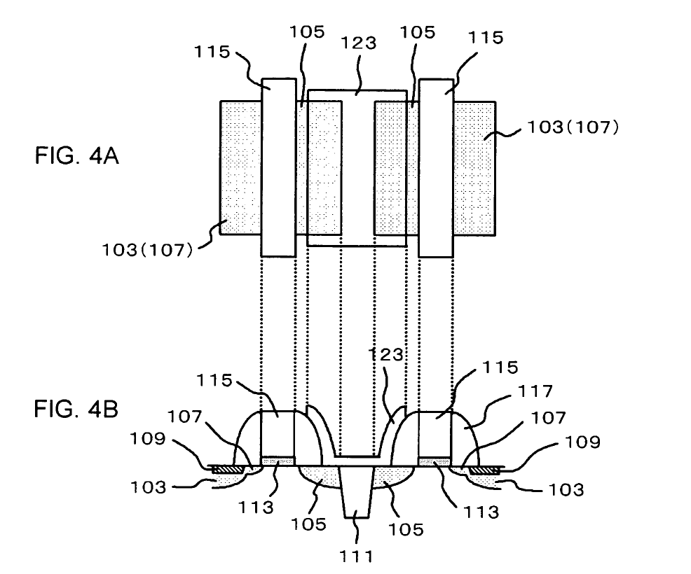

FIG. 4A and FIG. 4B are diagrams, illustrating an exemplary implementation having two MOSFETs shown in FIG. 1, which are disposed adjacent the silicon substrate 101. FIG. 4A is a plan view, showing a configuration of a semiconductor device in the present embodiment, and FIG. 4B is a cross-sectional view along the gate length direction of FIG. 4A.

A basic configuration of the semiconductor device shown in FIG. 4A and FIG. 4B is similar to that of the semiconductor device 100 described in reference to FIG. 1, except that two MOSFETs are disposed to be adjacent so that the respective gate electrodes 115 are in parallel. And the two MOSFETs are arranged so that the respective second impurity diffusion regions 105 having no extension region 107 are disposed to be adjacent. The respective second impurity diffusion regions 105 of the two MOSFETs are insulatively isolated by the element isolation region 111.

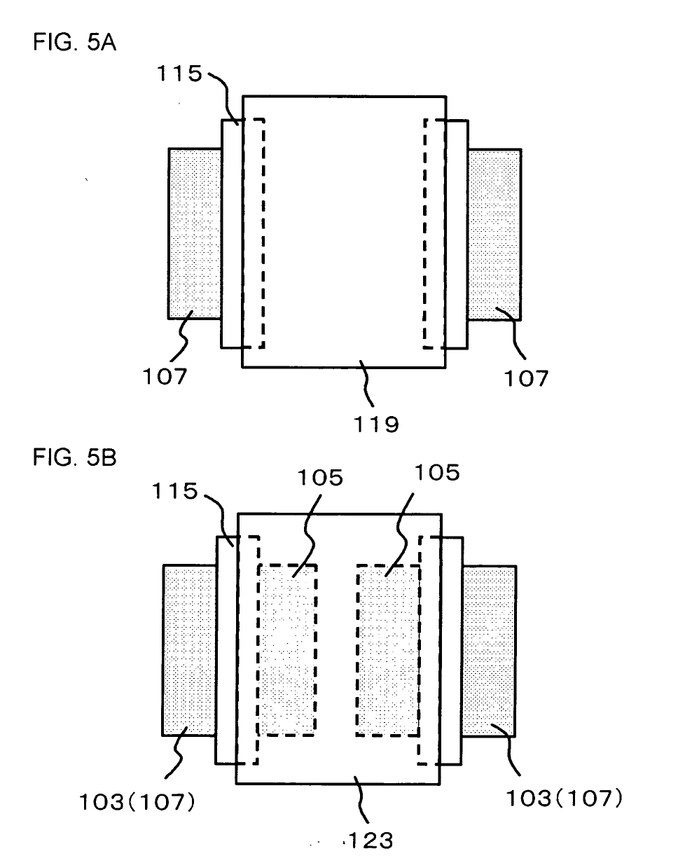

The semiconductor device shown in FIG. 4A and FIG. 4B may be produced according to the method of manufacturing the semiconductor device 100 shown in FIG. 1. FIG. 5A and FIG. 5B are cross-sectional views, describing the method of manufacturing the semiconductor device shown in FIG. 4A and FIG. 4B, and correspond to FIG. 2B and FIG. 3, respectively.

As shown in FIG. 4A, FIG. 4B, FIG. 5A and FIG. 5B, in the present configuration, common resist film 119 and silicon oxide film 123 may be formed over the second impurity diffusion regions 105 of the two MOSFETs. The silicon oxide film 123 functioning as a silicide block is provided to extend from the upper section of the gate electrode 115 in one MOSFET to the upper section of the gate electrode 115 in the other MOSFET, and covers the regions in vicinity of the ends of each of the two second impurity diffusion regions 105 in the side of the gate electrode 115. In FIG. 5A and FIG. 5B, the silicon oxide film 123 covers the entire two regions for forming the second impurity diffusion regions 105.

Since the configuration shown in FIG. 4A and FIG. 4B is employed, a plurality of asymmetric MOSFETs can be formed in the element formation surface of the silicon substrate 101 without any difficulty, and the junction leakage in a plurality of asymmetric MOSFETs can be inhibited. In addition, such configuration can provide more relaxed configuration due to wider line and space (L/S) in the formation of the silicon oxide film 123, achieving the configuration that can be more stably produced. In addition, it is not necessary to employ an exposure equipment of smaller minimum stroke width, achieving a simple manufacturing process.

While the embodiment employing polycrystalline silicon for the material of the gate electrode 115 have been described above, the material of the gate electrode 115 is not limited thereto, and for example, a metal gate may be employed. The use of a metal gate provides reduced gate resistance, and thus the operating characteristics of the MOSFET 110 can be further improved, when the entire second impurity diffusion region 105 is not silicidated.

### Second Embodiment

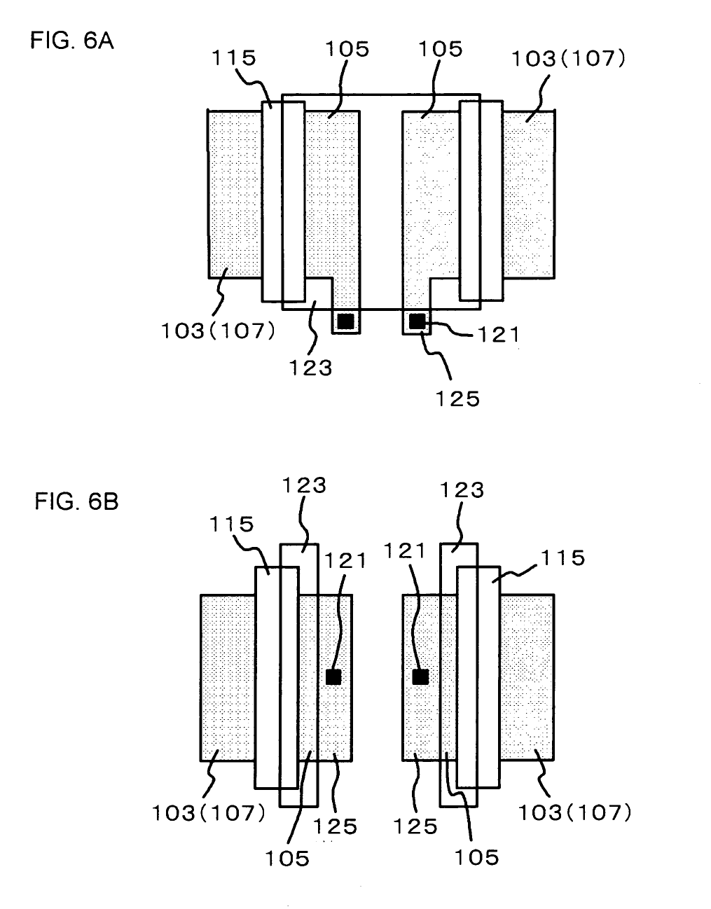

FIG. 6A and FIG. 6B are plan views, illustrating a configuration of a semiconductor device in the present embodiment. Basic configurations of the semiconductor devices respectively shown in FIG. 6A and FIG. 6B are similar to that of the device described in reference to FIG. 4A and FIG. 4B, except that both of the two second impurity diffusion regions 105 project from the region for forming the silicon oxide film 123, and that the respective projecting sections are silicidated and electroconductive coupling plugs 121 are provided so as to be in contact with the upper section of the respective silicide sections.

More specifically, in the configurations shown in FIG. 6A and FIG. 6B, the silicon oxide film 123, provided on the silicon substrate 101 and covering the second impurity diffusion region 105 in vicinity of the side edge of the gate electrode 115 is further included. Furthermore from the upper viewpoint, the silicon oxide film 123 is provided to partially overlapping with the second impurity diffusion region 105, and a second silicide layer 125 is provided on the second impurity diffusion region 105 in the region of the second impurity diffusion region 105 without overlapping with the silicon oxide film 123.

FIG. 6A illustrates an exemplary implementation, in which the second impurity diffusion region 105 includes a projecting section that projects from the region for forming the silicon oxide film 123 toward the gate width direction of the gate electrode 115, the projecting section is partially exposed out of the silicon oxide film 123, the second silicide layer 125 is provided on the second impurity diffusion region 105 in such exposed region, and the electroconductive coupling plug 121 is provided so as to be in contact with the second silicide layer 125. Furthermore in FIG. 6B, the second impurity diffusion region 105 projects from the region for forming the silicon oxide film 123 toward the gate length direction with a constant width.

The semiconductor device shown in FIG. 6A and FIG. 6B may be produced by employing the method of manufacturing the semiconductor devices shown in FIG. 1, FIG. 4A and FIG. 4B. More specifically, a step of forming the silicon oxide film 123 that partially covers the second impurity diffusion region 105 is employed for the step of forming the silicon oxide film 123 (step 14). Then, the second silicide layer 125 is formed in the upper section of the region of the second impurity diffusion region 105 without forming the silicon oxide film 123 in the step of forming the first silicide layer 109 (step 15). In addition, a step of forming the electroconductive coupling plug 121 so as to be in contact with the second silicide layer 125, after the second silicide layer 125 is formed, is further included.

The use of the configuration of the present embodiment achieves that the contact resistance in the second impurity diffusion region 105 can be further reduced, in addition to the advantageous effects of first embodiment.

### Third Embodiment

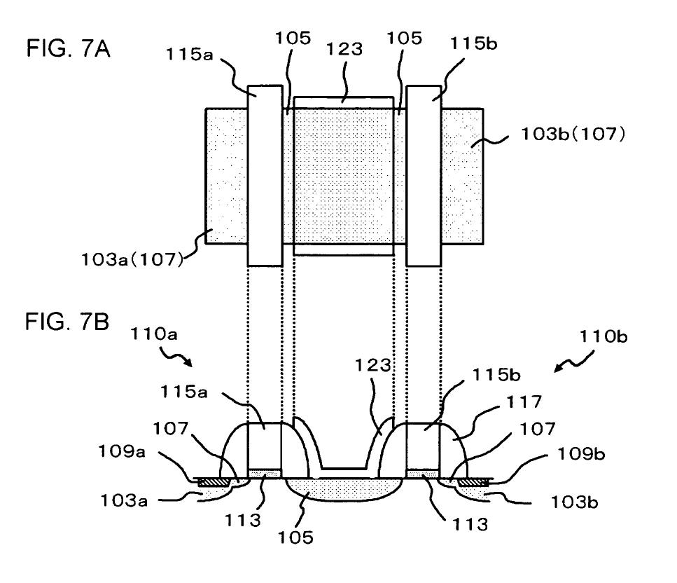

FIG. 7A and FIG. 7B are diagrams, illustrating a configuration of a semiconductor device in the present embodiment. FIG. 7A is a plan view, showing a configuration of a semiconductor device, and FIG. 7B is a cross-sectional view along the gate length direction of FIG. 7A.

A basic configuration of the semiconductor device shown in FIG. 7A and FIG. 7B is similar to that of the device described in reference to FIG. 4A and FIG. 4B, except that the two second impurity diffusion regions 105 of the asymmetric MOSFET are not element-isolated, and a common second impurity diffusion region 105 is provided.

The semiconductor device shown in FIG. 7A and FIG. 7B includes a first MOSFET 110a having a first impurity diffusion region 103a, a first silicide layer 109a, a second impurity diffusion region 105 and a first gate electrode 115a, and a second MOSFET 110b having a second impurity diffusion region 105, a third impurity diffusion region 103b, a third silicide layer 109b and a second gate electrode 115b. The second MOSFET 110b includes a second gate electrode 115b, which disposes adjacent the first gate electrode 115a across the second impurity diffusion region 105, and a third impurity diffusion region 103b, which disposes adjacent the second impurity diffusion region 105 across the second gate electrode 115b. The gate electrodes 115a and 115b of the two MOSFETs are disposed so as to be in parallel relationship, and the common second impurity diffusion region 105 is provided between the two gate electrodes 115a and 115b.

The second MOSFET 110b has the extension region 107 in the upper section of the third impurity diffusion region 103b and has no extension region in the upper section of the second impurity diffusion region 105, and the third silicide layer 109b on the third impurity diffusion region 103b and has no silicide layer in vicinity of the side edge of the second gate electrode 115b on the second impurity diffusion region 105.

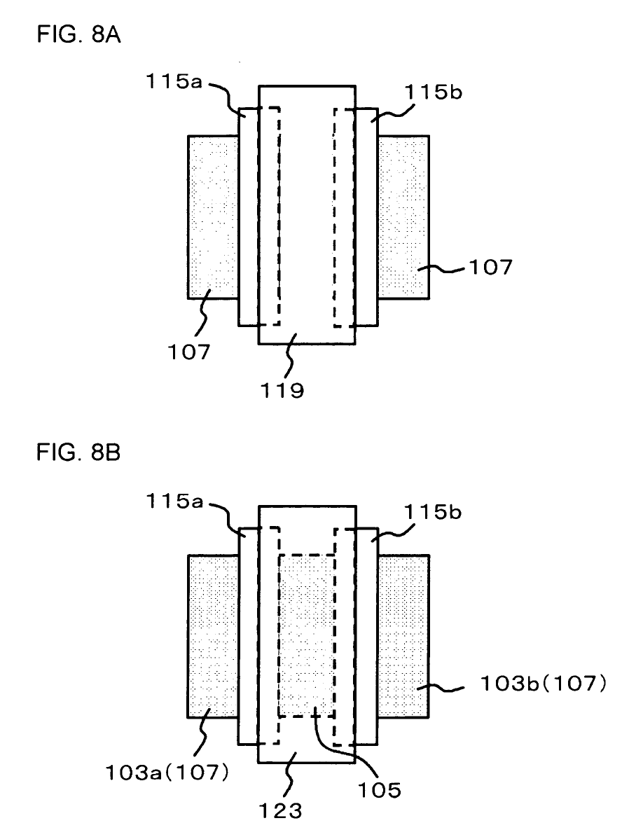

The semiconductor device shown in FIG. 7A and FIG. 7B may be produced according to the method of manufacturing the semiconductor devices shown in FIG. 1, FIG. 4A and FIG. 4B. FIG. 8A and FIG. 8B are cross-sectional views, describing the method of manufacturing the semiconductor device shown in FIG. 7A and FIG. 7B, and correspond to FIG. 5A and FIG. 5B, respectively.

Since the two transistors have the common source region or the common drain region in the present embodiment, degree of integration of the asymmetric MOSFET in the element formation surface of the silicon substrate 101 can be enhanced, in addition to the advantageous effects obtainable by employing the configuration shown in FIG. 4A and FIG. 4B. Thus, a dimensional area of a layout can be reduced. In addition, the second impurity diffusion region 105 may be utilized as a common source region, so that the device can be more preferably employed for a transistor composing a nonvolatile memory.

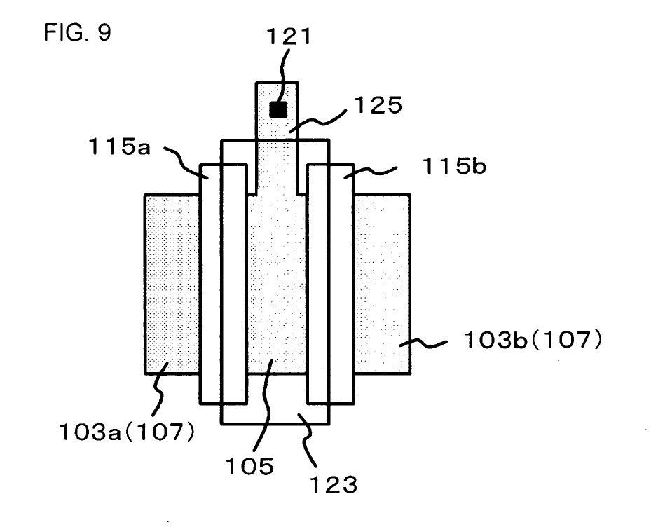

Alternatively, the configuration described in third embodiment may additionally be applied in the present embodiment. FIG. 9 is a plan view, illustrating a configuration of such semiconductor device. A basic configuration of the semiconductor device shown in FIG. 9 is similar to that of the device described in reference to FIG. 7A, except that the second impurity diffusion region 105 projects toward the gate width direction and a portion of the projecting section is not covered by the silicon oxide film 123, the region without being covered by the silicon oxide film 123 serves as the second silicide layer 125, and the coupling plug 121 is provided so as to be in contact with the second silicide layer 125. Having such configuration, an increase of the contact resistance in the second impurity diffusion region 105 can be further inhibited, in addition to the advantageous effects obtainable by employing the configuration shown in FIG. 7A.

### Fourth Embodiment

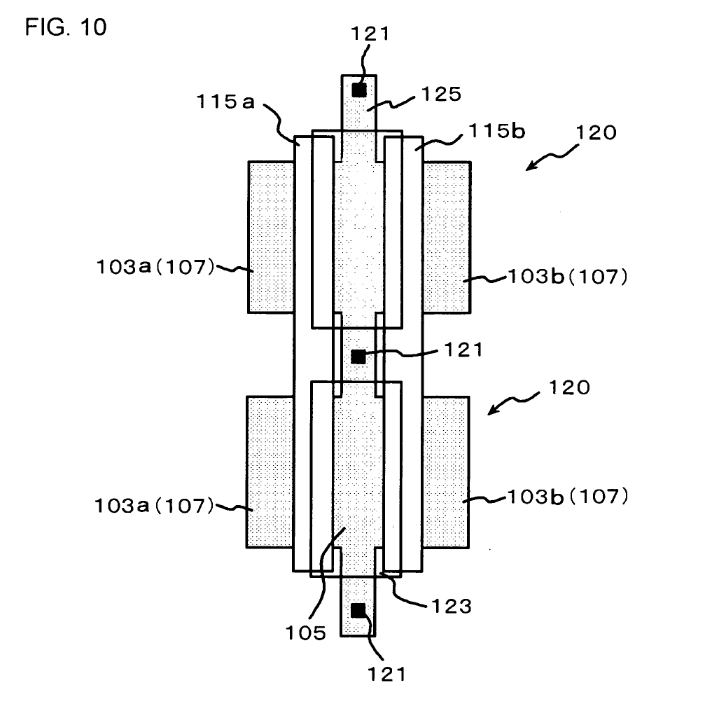

FIG. 10 is a plan view, illustrating configuration of a semiconductor device. In the semiconductor device having the basic configuration shown in FIG. 9, plurality of pairs of asymmetric MOSFETs aligned in line may be arranged along the gate width direction.

A plurality of transistor pairs 120, each of which is composed of a first MOSFET 110a and a second MOSFET 110b, are provided in the semiconductor device shown in FIG. 10. The plurality of transistor pairs 120 are aligned in line along the elongating direction of the first gate electrode 115a and the second gate electrode 115b, and are commonly provided with the second impurity diffusion region 105. The second impurity diffusion region 105 includes a projecting section projecting along the gate width direction of the first gate electrode 115a from the region for forming the silicon oxide film 123. In the projecting section, the second silicide layer 125 is provided on the second impurity diffusion region 105, and the coupling plug 121 is provided so as to be in contact with the second silicide layer 125.

The semiconductor device shown in FIG. 10 may be produced according to the method of manufacturing the semiconductor devices described in first to third embodiments.

More specifically, in the step of forming the first gate electrode 115a (step 11), the second gate electrode 115b adjacent the first gate electrode 115a is formed in the upper section of the silicon substrate 101.

In the step of forming the extension region 107 (step 12), an impurity of a first type conductivity (for example, n-type) is ion-implanted in the upper section of the regions for forming the first impurity diffusion region 103a and the third impurity diffusion region 103b to form the extension regions 107. No extension region is formed in the upper section of the region for forming the second impurity diffusion region 105.

In addition, the step of forming the first impurity diffusion region 103a and the second impurity diffusion region 105 (step 13) includes a step of forming the second impurity diffusion region 105 disposed between the first gate electrode 115a and the second gate electrode 115b and the first impurity diffusion region 103a facing the second impurity diffusion region 105 across the first gate electrode 115a, and forming the third impurity diffusion region 103b facing the second impurity diffusion region 105 across the second gate electrode 115b.

The step of forming the silicon oxide film 123 (step 14) includes a step of forming the silicon oxide film 123, which covers the upper section of the second impurity diffusion region 105 in vicinity of the side edge of the first gate electrode 115a and in vicinity of the side edge of the second gate electrode 115b and partially covers the second impurity diffusion region 105.

In the step of forming the first silicide layer 109 (step 15), the first silicide layer 109a and the third silicide layer 109b are formed in the upper sections of the first impurity diffusion region 103a and the third impurity diffusion region 103b, respectively, and the second silicide layer 125 is formed in the upper section of the region of the second impurity diffusion region 105 without forming the silicon oxide film 123. The step further includes a step of forming the electroconductive coupling plug 121 so as to be in contact with the second silicide layer 125.

According to the present embodiment, as in the above-mentioned embodiments, a junction leakage in the asymmetric MOSFET can be inhibited and an increase of the contact resistance in the second impurity diffusion region 105 can be inhibited, and further, a dimensional area of a layout of the asymmetric MOSFET can be reduced.

While the exemplary implementation has been described above in FIG. 10, in which three second silicide layers 125 are provided in the outer portions of the two transistor pairs in the gate width direction and in the region between the transistor pairs and a single coupling plug 121 is provided in each of the second silicide layer 125, the arrangement of the coupling plug 121 is not limited thereto.

While the preferred embodiments of the present invention have been described above in reference to the annexed figures, it should be understood that the disclosures above are presented for the purpose of illustrating the present invention, and various modifications other than that described above are also available.

While the exemplary implementation has been described in the above-described embodiment, in which, for example, the first impurity-diffused region 103 (first impurity-diffused region 103a) and the third impurity-diffused region 103b serve as the drain regions and the second impurity-diffused region 105 serves as the source region, the locations of the source region and the drain region may be inverted.

It is apparent that the present invention is not limited to the above embodiment, and may be modified and changed without departing from the scope and spirit of the invention.

What is claimed is:

1. A semiconductor device, comprising a first field effect transistor having:
a first gate electrode provided over a silicon substrate; and
a first and a second impurity diffusion regions provided in said silicon substrate in different sides of said first gate electrode,
wherein said first field effect transistor has an extension region in an upper section of said first impurity diffusion region and no extension region in an upper section of said second impurity diffusion region, and has a first silicide layer over said first impurity diffusion region and has no silicide layer over said second impurity diffusion region in vicinity of a side edge of said first gate electrode.

2. The semiconductor device as set forth in claim 1, further comprising a second field effect transistor comprising:
said second impurity diffusion region;
a second gate electrode disposed adjacent said first gate electrode across said second impurity diffusion region; and
a third impurity diffusion region disposed adjacent said second impurity diffusion region across said second gate electrode,
wherein said second field effect transistor has an extension region in an upper section of said third impurity diffusion region and no extension region in an upper section of said second impurity diffusion region, and has a third silicide layer over said third impurity diffusion region and has no silicide layer in vicinity of a side edge of said second gate electrode over said second impurity diffusion region.

3. The semiconductor device as set forth in claim 2, further comprising a plurality of transistor pairs composed of said first and said second field effect transistors,
wherein said transistor pairs are aligned along an elongating direction of said the first and said second gate electrodes and said second impurity diffusion region is provided commonly in said transistor pairs,
wherein said second impurity diffusion region includes a projecting section that projects along a direction from a region for forming an insulating film toward the gate width of said first gate electrode,
wherein a second silicide layer is provided on said second impurity diffusion region in said projecting section, and
wherein an electroconductive coupling plug is provided so as to be in contact with said second silicide layer.

4. The semiconductor device as set forth in claim 1, wherein said first impurity diffusion region is a drain region of said first field effect transistor, and said second impurity diffusion region is a source region of said first field effect transistor.

5. The semiconductor device as set forth in claim 2, wherein said first impurity diffusion region is a drain region of said first field effect transistor, and said second impurity diffusion region is a source region of said first field effect transistor.

6. The semiconductor device as set forth in claim 3, wherein said first impurity diffusion region is a drain region of said first field effect transistor, and said second impurity diffusion region is a source region of said first field effect transistor.

7. A method of manufacturing a semiconductor device, comprising:
forming a first gate electrode in an upper section of a silicon substrate;
ion-implanting an impurity of a first type conductivity selectively in one side of said first gate electrode to form an extension region;
implanting the impurity of the first type conductivity in a section of said silicon substrate around said first gate electrode to form a first impurity diffusion region in said one side of said first gate electrode and to form a second impurity diffusion region facing said first impurity diffusion region across said first gate electrode;
forming an insulating film so as to cover the upper section of said second impurity diffusion region in vicinity of said side edge of said first gate electrode; and
forming a metallic film on an element formation surface of said silicon substrate having said insulating film provided thereon, and then causing a reaction of a metal in said metallic film with silicon in said silicon substrate to form a first silicide layer in the upper section of said first impurity diffusion region.

8. The method of manufacturing the semiconductor device as set forth in claim 7,
wherein said step of forming the insulating film includes forming said insulating film so as to cover a portion of the upper section of said second impurity diffusion region, and
wherein said step of forming said first silicide layer includes forming a second silicide layer in the upper section of a region of said second impurity diffusion region without forming said insulating film and forming an electroconductive coupling plug so as to be in contact with said second silicide layer.

9. The method of manufacturing the semiconductor device as set forth in claim 7,
wherein said step of forming said first gate electrode includes forming a second gate electrode in an upper section of said silicon substrate so as to be adjacent said first gate electrode,
wherein said step of forming said extension region includes ion-implanting the impurity of first type conductivity in the upper section of a region for forming said first impurity diffusion region and a third impurity diffusion region to form said extension region,
wherein said step of forming said first and second impurity diffusion regions includes forming said second impurity diffusion region disposed between said first and said second gate electrodes and forming said first impurity diffusion region disposed in the opposite side of said second impurity diffusion region across said first gate electrode and forming a third impurity diffusion region in the opposite side of said second impurity diffusion region across said second gate electrode,
wherein said step of forming the insulating film includes forming said insulating film that covers the upper section of said second impurity diffusion region in vicinity of the side edge of said first gate electrode and in vicinity of the side edge of said second gate electrode and a portion of the upper section of said second impurity diffusion region, and
wherein said step of forming said first silicide layer includes forming said first silicide layer and said third silicide layer in the upper section of said first and said third impurity diffusion region and forming said second silicide layer in an upper section of a region of said second impurity diffusion region without forming said insulating film and forming an electroconductive coupling plug so as to be in contact with said second silicide layer.

10. The method of manufacturing the semiconductor device as set forth in claim 8,
wherein said step of forming said first gate electrode includes forming a second gate electrode in an upper section of said silicon substrate so as to be adjacent said first gate electrode,
wherein said step of forming said extension region includes ion-implanting the impurity of first type conductivity in the upper section of a region for forming said first impurity diffusion region and a third impurity diffusion region to form said extension region,
wherein said step of forming said first and second impurity diffusion regions includes forming said second impurity diffusion region disposed between said first and said second gate electrodes and forming said first impurity diffusion region disposed in the opposite side of said second impurity diffusion region across said first gate electrode and forming a third impurity diffusion region in the opposite side of said second impurity diffusion region across said second gate electrode,
wherein said step of forming the insulating film includes forming said insulating film that covers the upper section of said second impurity diffusion region in vicinity of the side edge of said first gate electrode and in vicinity of the side edge of said second gate electrode and a portion of the upper section of said second impurity diffusion region, and
wherein said step of forming said first silicide layer includes forming said first silicide layer and said third silicide layer in the upper section of said first and said third impurity diffusion region and forming said second silicide layer in an upper section of a region of said second impurity diffusion region without forming said insulating film and forming an electroconductive coupling plug so as to be in contact with said second silicide layer.
